(19) United States
(12) Patent Application Publication
(10) Pub. No.: US 2025/0105049 A1
(43) Pub. Date: Mar. 27, 2025

(54) SUBSTRATE PROCESSING APPARATUS AND METHOD

(71) Applicant: Semes Co., Ltd, Cheonan-si (KR)

(72) Inventors: Seung Eun NA, Bucheon-si (KR); Dae Hun KIM, Pyeongtaek-si (KR); Hyun Woo BAE, Seoul (KR); Seong Hyeon KIM, Cheonan-si (KR)

(73) Assignee: Semes Co., Ltd, Cheonan-si (KR)

(21) Appl. No.: 18/896,026

(22) Filed: Sep. 25, 2024

(30) Foreign Application Priority Data
Sep. 25, 2023 (KR) 10-2023-0128371

(51) Int. Cl. H01L 21/687; H01L 21/67

(52) U.S. Cl. CPC H01L 21/68742; H01L 21/67023

(57) ABSTRACT

Disclosed is a substrate processing apparatus including: a processing container having a processing space therein; a support unit for supporting and rotating a substrate within the processing space; and a nozzle unit for supplying a treatment solution to the substrate, in which the processing container includes a plurality of cups that encloses the processing space and is provided so that openings through which the treatment solution is introduced are stacked in an up and down direction, and each of the plurality of cups includes: a sidewall; and an upper wall extending from the sidewall toward the processing space, and an inner end of an upper wall of a first cup, of which the upper wall is located at the uppermost side among the plurality of cups, protrudes further toward the processing space than an inner end of an upper wall of another cup.

### CROSS-REFERENCE TO RELATED APPLICATIONS

This application claims priority to and the benefit of Korean Patent Application No. 10-2023-0128371 filed in the Korean Intellectual Property Office on Sep. 25, 2023, the entire contents of which are incorporated herein by reference.

### TECHNICAL FIELD

The present invention relates to an apparatus and a method of liquid-treating a substrate.

### BACKGROUND ART

In general, in a process of treating a glass substrate or a wafer in a process of manufacturing a flat panel display device or a semiconductor, various processes, such as a photoresist coating process, a developing process, an etching process, and an ashing process, are performed. In each process, in order to remove various contaminants attached to the substrate, a wet cleaning process using a chemical liquid or deionized water and a drying process for drying the chemical liquid or the deionized water left on the surface of the substrate are performed.

The process of processing a substrate with a liquid among respective processes includes the operation of supplying a liquid, such as a chemical liquid, to the substrate and rotating the substrate. During this operation, as the substrate rotates, the chemical liquid and the like are applied onto the substrate and react with the substrate.

In this case, as the substrate rotates, the chemical liquid and the like are scattered off the substrate. The chemical liquid may be scattered into the interior of a processing container, which provides a processing space for processing the substrate, but may also be scattered beyond an opening of the processing container.

In particular, the opening of the processing container is necessarily provided to be larger than the substrate to avoid interference with the chuck pin supporting the substrate from the side when the substrate enters. The processing container is vulnerable to external scattering through the opening, as the opening is provided wider than the width of the substrate. Externally sprayed chemical liquid and the like are fixed on the outside of the processing container and generates fume, and the substrate may be contaminated by particles from the fume during substrate processing.

### SUMMARY OF THE INVENTION

The present invention has been made in an effort to provide a substrate processing apparatus capable of minimizing scattering to the outside of a processing container when a substrate is rotated for liquid treatment.

The present invention has also been made in an effort to provide a substrate processing apparatus capable of cleaning the exterior of a processing container.

The object of the present invention is not limited thereto, and other objects not mentioned will be clearly understood by those of ordinary skill in the art from the following description.

An exemplary embodiment of the present invention provides a substrate processing apparatus including: a processing container having a processing space therein; a support unit for supporting and rotating a substrate within the processing space; and a nozzle unit for supplying a treatment solution to the substrate, in which the processing container includes a plurality of cups that encloses the processing space and is provided so that openings through which the treatment solution is introduced are stacked in an up and down direction, and each of the plurality of cups includes: a sidewall; and an upper wall extending from the sidewall toward the processing space, and an inner end of an upper wall of a first cup, of which the upper wall is located at the uppermost side among the plurality of cups, protrudes further toward the processing space than an inner end of an upper wall of another cup.

According to the exemplary embodiment, a groove may be formed in the inner end of the upper wall of the first cup.

According to the exemplary embodiment, the support unit may include: a support plate on which the substrate is placed; and a plurality of chuck pins provided to protrude upwardly from a top surface of the support plate, and supporting a lateral portion of the substrate when the substrate is processed.

According to the exemplary embodiment, the chuck pin may be inserted into the groove when a top end of the chuck pin is moved to a position higher than the inner end of the upper wall of the first cup.

According to the exemplary embodiment, the inner end of the upper wall of the first cup may have a shorter distance to a center axis of the support plate than an outer end of the chuck pin when viewed from above.

According to the exemplary embodiment, the chuck pin may be provided to be movable between a support position supporting the substrate and a standby position releasing the support of the substrate, and a top end of the chuck pin may pass through the groove when moved to a position higher than the inner end of the upper wall of the first cup while the chuck pin is in the standby position.

According to the exemplary embodiment, the inner end of the upper wall of the first cup may be provided to be sloped upwardly toward a center axis of the first cup.

According to the exemplary embodiment, the upper wall of the first cup may include a body part and a protrusion, when the body part is viewed from above, an inner end of the body part may coincide with the inner end of the upper wall of the another cup, the protrusion may be detachably provided to the inner end of the body part, and the groove may be formed in an inner end of the protrusion.

Another exemplary embodiment of the present invention provides a substrate processing apparatus including: a processing container having a shape of a barrel with an open top and providing a processing space; a support unit for supporting and rotating a substrate within the processing space; and a liquid supply unit for supplying a treatment solution to the substrate supported on the support unit, in which the processing container includes: a sidewall provided in a ring shape and surrounding the support unit; and an upper wall extending from a top end of the sidewall towards a central axis of the support unit, and a groove is formed at an inner end of the upper wall.

According to the exemplary embodiment, the support unit may include: a support plate on which the substrate is placed; and a plurality of chuck pins provided to protrude upwardly from a top surface of the support plate, and supporting a lateral portion of the substrate when the substrate is processed.

According to the exemplary embodiment, the chuck pin may be provided to be movable between a support position supporting the substrate and a standby position releasing the support of the substrate, and a top end of the chuck pin may pass through the groove when moved to a position higher than the upper wall while the chuck pin is in the standby position.

According to the exemplary embodiment, the inner end of the upper wall may be provided to be closer to a center axis of the support plate than an outer end of the chuck pin in the standby position when viewed from above.

According to the exemplary embodiment, the groove may be formed at a position corresponding to the standby position.

According to the exemplary embodiment, the groove may be provided for insertion of the chuck pin when the top end of the chuck pin is moved to a position higher than the upper wall.

According to the exemplary embodiment, the chuck pin may be provided such that, when viewed from above, the outer end of the chuck pin at the support position is closer to the center axis of the support plate than the inner end of the upper wall.

According to the exemplary embodiment, the upper wall may be provided to be sloped upwardly toward the center axis of the support plate.

According to the exemplary embodiment, a portion extending from the upper wall may be a protrusion, and the upper wall and the protrusion may be separable.

Still another exemplary embodiment of the present invention provides a substrate processing apparatus including: a processing container having a processing space therein; a support unit for supporting and rotating a substrate within the processing space; and a nozzle unit for supplying a treatment solution to the substrate, in which the processing container includes a plurality of cups that encloses the processing space and is provided so that openings through which the treatment solution is introduced are stacked in an up and down direction, each of the plurality of cups includes: a sidewall; and an upper wall extending from the sidewall toward the processing space, and an inner end of an upper wall of a first cup, of which the upper wall is located at the uppermost side among the plurality of cups, protrudes further toward the processing space than an inner end of an upper wall of another cup, a groove is formed in the inner end of the upper wall of the first cup, the chuck pin is provided to be movable between a support position supporting the substrate and a standby position releasing the support of the substrate, and the groove is provided for insertion of the chuck pin when the top end of the chuck pin is moved to a position higher than the inner end of the upper wall of the first cup while the chuck pin is in the standby position.

According to the exemplary embodiment, the plurality of cups may further include a second cup, the second cup may be located inside the first cup, an upper wall of the second cup may be provided parallel to the upper wall of the first cup, but may be located lower than the upper wall of the first cup, and the substrate processing apparatus may further include a lifting member for adjusting a relative height of the first cup and the second cup.

According to the exemplary embodiment, the upper walls may be provided to be sloped upwardly toward a center axis of the support unit.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a top plan view schematically illustrating a substrate processing apparatus according to an exemplary embodiment of the present invention.

FIG. 2 is a diagram schematically illustrating an exemplary embodiment of a liquid treating chamber of FIG. 1.

FIG. 3 is a diagram schematically illustrating the liquid treating chamber of FIG. 2, viewed from above.

FIG. 4 is a flowchart illustrating a method of processing a substrate by using the liquid treating chamber of FIG. 2.

FIGS. 5 to 7 are cross-sectional views illustrating an operation of the liquid treating chamber during a substrate loading operation of FIG. 4.

FIG. 8 is a diagram illustrating the cleaning of the exterior of a processing container.

FIG. 9 is a diagram schematically illustrating another exemplary embodiment of the present invention.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to” or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

The foregoing detailed description illustrates the present invention. Further, the above content illustrates and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

In the present exemplary embodiment, the present invention is described based on a process for cleaning a substrate by using a treatment solution as an example. However, the present exemplary embodiment is not limited to a cleaning process, but may be applied to various substrate processing processes using a liquid, such as an etching process, an ashing process, and a development process.

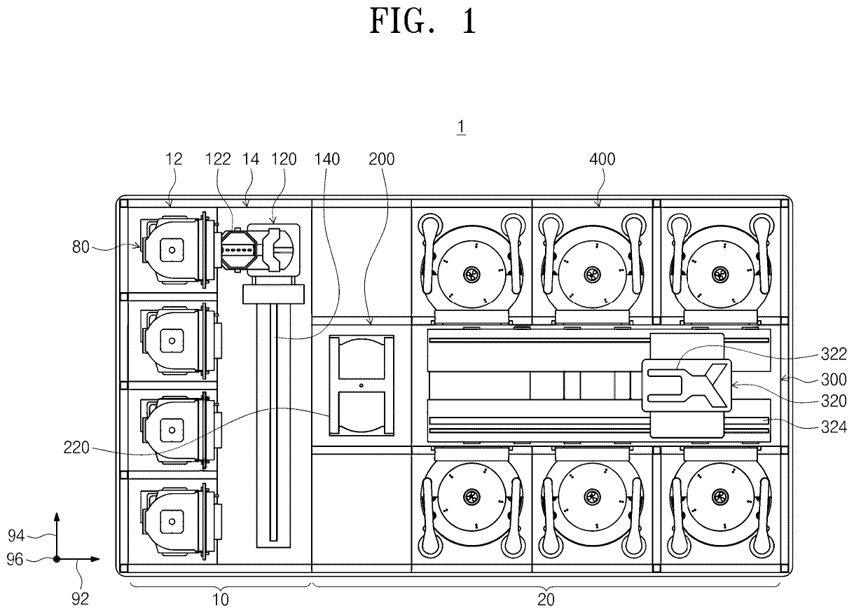

FIG. 1 is a top plan view schematically illustrating a substrate processing apparatus according to an exemplary embodiment of the present invention.

Referring to FIG. 1, the substrate processing apparatus includes an index module 10, a treating module 20, and a controller 30. According to the exemplary embodiment, the index module 10 and the treating module 20 are disposed along one direction. Hereinafter, the direction in which the index module 10 and the treating module 20 are disposed is referred to as a first direction 92, and when viewed from above, a direction vertical to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transport means (not illustrated), such as an overhead transfer, an overhead conveyor, or an automatic guided vehicle, or an operator.

An index robot 120 is provided to the index frame 14. A guide rail 140 of which a longitudinal is the second direction 94 is provided within the index frame 14, and the index robot 120 may be provided to be movable on the guide rail 140. The indexing robot 120 includes a hand 122 on which the substrate W is placed, and the hand 122 may be provided to be movable forward and backward, rotatable about the third direction 96, and movable along the third direction 96. A plurality of hands 122 are provided to be spaced apart in the vertical direction, and the hands 122 may move forward and backward independently of each other.

The treating module 20 includes a buffer unit 200, a transfer chamber 300, and a liquid treating chamber 400. The buffer unit 200 provides a space in which the substrate W loaded into the treating module 20 and the substrate W unloaded from the treating module 20 stay temporarily. The liquid treating chamber 400 performs a treatment process of liquid-treating the substrate W by supplying a liquid onto the substrate W. The transfer chamber 300 transfers the substrate W between the buffer unit 200 and the liquid treating chamber 400.

The transfer chamber 300 may be provided so that a longitudinal direction is the first direction 92. The buffer unit 200 may be disposed between the index module 10 and the transfer chamber 300. A plurality of liquid treating chambers 400 is provided and may be disposed on the side of the transfer chamber 300. The liquid treating chamber 400 and the transfer chamber 300 may be disposed in the second direction 94. The buffer unit 200 may be located at one end of the transfer chamber 300.

According to the example, the liquid treating chambers 400 are respectively disposed on both sides of the transfer chamber 300. At each of both sides of the transfer device 300, the liquid treating devices 400 may be provided in an array of A×B (each of A and B is 1 or a natural number larger than 1) in the first direction 92 and the third direction 96.

The transfer chamber 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 in which the substrate W is placed, and the hand 322 may be provided to be movable forward and backward, rotatable about the third direction 96, and movable along the third direction 96. A plurality of hands 322 are provided to be spaced apart in the vertical direction, and the hands 322 may move forward and backward independently of each other.

The buffer unit 200 includes a plurality of buffers 220 on which the substrate W is placed. The buffers 220 may be disposed while being spaced apart from each other in the third direction 96. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

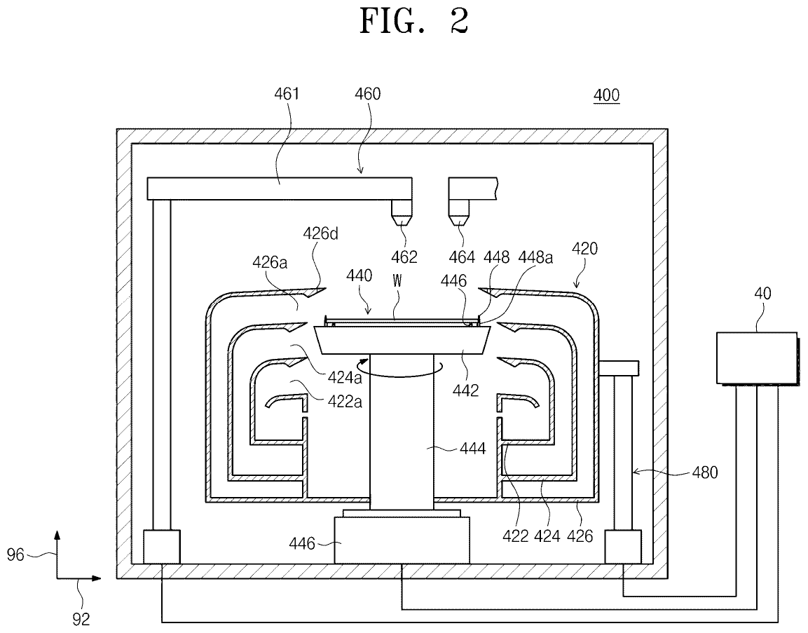

FIG. 2 is a diagram schematically illustrating an exemplary embodiment of the liquid treating chamber 400 of FIG. 1. Referring to FIG. 2, the liquid treating chamber 400 has a housing 410, a processing container 420, a support unit 440, a nozzle unit 460, a lifting unit 480, a liquid supply unit 460, and a controller.

The housing 410 is provided in a generally rectangular parallelepiped shape. The processing container 420, the support unit 440, and the nozzle unit 460 are disposed within the housing 410.

The processing container 420 has a processing space with an open top, and the substrate W is liquid-treated within the processing space. The support unit 440 supports the substrate W in the processing space. The liquid supply unit 460 supplies the liquid onto the substrate W supported by the support unit 440. The liquid may be provided in a plurality of types, and may be sequentially supplied onto the substrate W. The lifting unit 480 adjusts the relative height between the processing container 420 and the support unit 440.

In one example, the processing container 420 has a plurality of cups 422, 424, and 426. Each of the cups 422, 424, and 426 has a collection space for collecting liquid used to process the substrate. Each of the cups 422, 424, and 426 is provided in the shape of a ring that surrounds the support unit 440. During the liquid treatment process, the treatment solution that is scattered by the rotation of the substrate W enters the collection spaces through the inlets 422a, 424a, and 426a of the respective cups 422, 424, and 426. In one example, the processing container 420 has a first cup 426, a second cup 424, and a third cup 422. The first cup 426 is disposed to enclose the support unit 440, the second cup 424 is disposed to enclose the first cup 426, and the third cup 422 is disposed to enclose the second cup 424. The second inlet 424e for receiving liquid into the second cup 424 may be positioned above the first inlet 426e for receiving liquid into the first cup 426, and the third inlet 422e for receiving liquid into the third cup 422 may be positioned above the second inlet 424e.

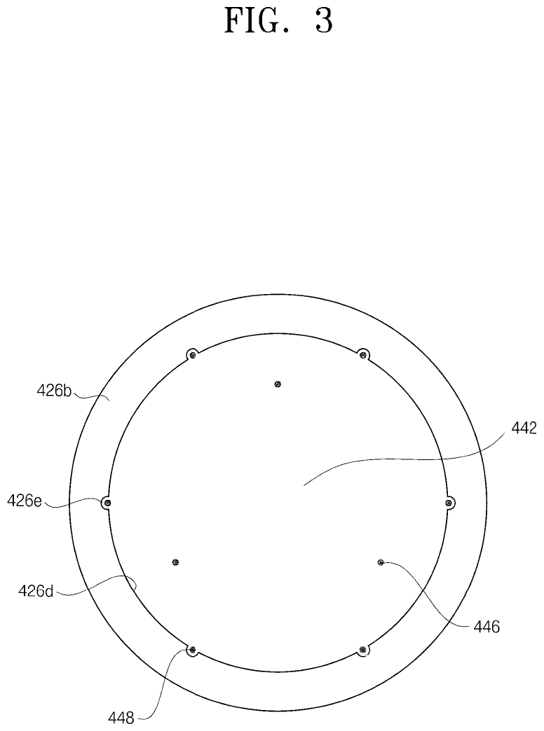

FIG. 3 is an enlarged view of some of the cups and the support unit in the liquid processing chamber of FIG. 2. Referring now to FIG. 3, the first cup 426, the second cup 424, and the third cup 422 are described in more detail.

The first cup 426 includes a sidewall 426a, an upper wall 426b, and a protrusion 426c. The sidewall 426a is provided in an annular ring shape. The sidewall 426a is provided to enclose a sidewall 424a. The sidewall 426a is installed on a guide rail. The sidewall 426a is movable along the longitudinal direction of the guide rail. The upper wall 426b is provided in the shape of a ring extending inwardly from an inner surface of the sidewall 426a. The upper wall 426b is provided to slope upwardly from the sidewall 426a toward the center axis of the support plate 342. The upper wall 426b extends to have a smaller inner diameter than the upper walls 424b and 422b. An inner end 426d of the upper wall 426b may extend to be closer to the center axis of the support plate 442 than an outer end 448a of a chuck pin 448, which will be discussed later. The upper wall 426b may extend to an extent such that interference between the first cup 426 and the substrate W does not occur when loading or unloading the substrate W. The inner end 426d of the upper wall 426b is provided with a groove 426e. In one example, the groove 426e may be provided at a location corresponding to the location where the chuck pin 448 is provided, as viewed from above. Further, the grooves 426e may be provided in the same number as the chuck pins 448. The protrusion 426c is provided in a ring shape extending downwardly from a distal end of the upper wall 426b. When viewed from the side, the bottom end of the protrusion 426c may be positioned higher than the bottom end of the upper wall 426b.

The second cup 424 includes a sidewall 424a, an upper wall 424b, and a protrusion 424c. The sidewall 424a is provided in an annular ring shape. The sidewall 424a is positioned between a sidewall 422a and the sidewall 426a. The upper wall 424b is provided in a ring shape extending inwardly from the top end of the sidewall 424a. The upper wall 424b is provided be sloped upwardly from the sidewall 424a. The upper wall 424b is provided to have an opening of the same inner diameter as the upper wall 422b. The protrusion 424c is provided in a ring shape extending downwardly from a distal end of the upper wall 424b. When viewed from the side, the bottom end of the protrusion 424c may be positioned higher than the bottom end of the upper wall 424b. A bottom surface portion 424d extends inwardly from the bottom end of the sidewall 424a.

The third cup 422 includes a sidewall 422a, an upper wall 422b, and a protrusion 422c. The sidewall 422a is provided in an annular ring shape. The sidewall 422a is provided to have a smaller inner diameter compared to the support sidewall 428a. The upper wall 422b is provided in a ring shape extending inwardly from the top end of the sidewall 422a. The upper wall 422b is provided to face in an upwardly sloping direction from the sidewall 422a. The protrusion 422c is provided in a ring shape extending downwardly from a distal end of the upper wall 422b. When viewed from the side, the bottom end of the protrusion 422c may be positioned higher than the bottom end of the upper wall 422b.

The support unit 440 includes the support plate 442, a drive shaft 444, a support pin 446, and the chuck pin 448. A top surface of the support plate 442 may be provided in a generally circular shape, and may have a diameter larger than a diameter of the substrate W. The support pin 446 is provided in the center of the support plate 442 to support the rear surface of the substrate W, and the support pin 446 is provided with a top end protruding from the support plate 442 such that the substrate W is spaced a certain distance from the support plate 442. The chuck pins 448 are provided at the edge of the support plate 442. A plurality of chuck pins 448 is provided. The chuck pin 448 is disposed farther from the center of the support plate 442 than the support pin 446. The chuck pins 448 are provided to protrude upwardly from the top surface of the support plate 442. The chuck pin 448 supports a lateral portion of the substrate W to prevent the substrate W from laterally deviating from a fixed position when the substrate W is rotated. The chuck pin 448 is provided to be linearly movable between a standby position A1 and a support position A2 along a radial direction of the support plate 442. The standby position A1 is a position further away from the center of the support plate 442 than the support position A2. When the substrate W is loaded into or unloaded from the substrate support unit 440, the chuck pin 448 is positioned in the standby position A1, and when a process is performed on the substrate W, the chuck pin 448 is positioned in the support position A2. In the support position A2, the chuck pin 448 is in contact with the lateral portion of the substrate W. The drive shaft 444 is driven by a driver 446, is connected to the center of the bottom surface of the substrate W, and rotates the support plate 442 with respect to the central axis thereof. The drive shaft 444 is provided in the shape of a barrel with its longitudinal direction facing up and down. The drive shaft 444 is fixedly coupled to the bottom surface of the support plate 442. The driver 446 provides driving force to the drive shaft 444 to rotate the drive shaft 444. When the driver 446 provides drive force to the drive shaft 444, the support plate 442 and the drive shaft 444 are rotated together.

The nozzle unit 460 includes a first nozzle 462 and a second nozzle 464. The first nozzle 462 supplies the treatment solution onto the substrate W. The treatment solution may be a cleaning solution. In one example, the cleaning solution may be water. The water may be pure water or deionized water.

The first nozzle 462 and the second nozzle 464 are respectively supported on different arms 461, and the arms 461 may be moved independently. Optionally, the first nozzle 462 and the second nozzle 464 may be mounted on the same arm and moved at the same time.

Optionally, the nozzle unit may further include one or more nozzles, in addition to the first nozzle 462 and the second nozzle 464. Additional nozzles may supply different types of treatment solutions to the substrate. For example, the other type of treatment solution may be an acid solution or a base solution for removing foreign substances on the substrate. In addition, another type of treatment solution may be alcohol having surface tension lower than that of water. For example, the alcohol may be isopropyl alcohol.

The lifting unit 480 moves the processing container 420 in a straight line in an up and down direction. By the up and down movement of the processing container 420, the relative height between the processing container 420 and the substrate W changes. This changes the cups 422, 424, and 426 that collect the treatment solution according to the type of liquid supplied to the substrate W, so that the liquid may be collected separately. The lifting unit 480 includes a connection member 482, a movement shaft 484, and a driver 486. The movement shaft 484 is positioned at one side of the processing container 420. The connection member 482 connects the movement shaft 484 and the sidewall 426a to each other. When the movement shaft 484 is moved in an up and down direction by the driver 486, the processing container 420 is movable with the movement shaft 484. Unlike the above description, the processing container 420 may fixedly installed, and the lifting unit 480 is capable of moving the support unit 440 in an up and down direction.

Hereinafter, a method of processing a substrate W by using the substrate processing apparatus described above will be described.

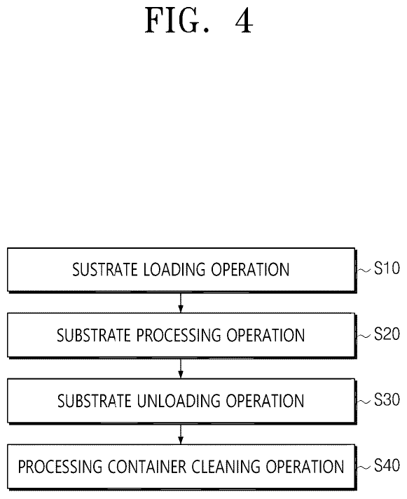

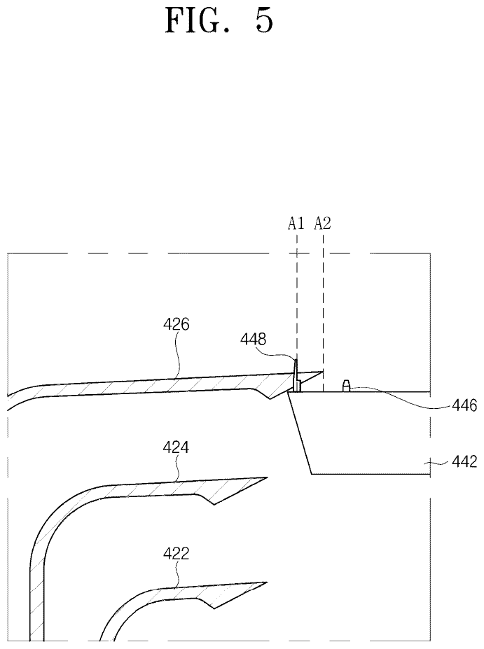

FIG. 4 is a flowchart illustrating a process of processing a substrate, and FIGS. 5 to 7 are diagrams illustrating a substrate loading operation of FIG. 4 in chronological order.

Referring to FIG. 4, a method of processing a substrate includes a substrate loading operation S10, a substrate processing operation S20, a substrate unloading operation S30, and a processing container cleaning operation S40.

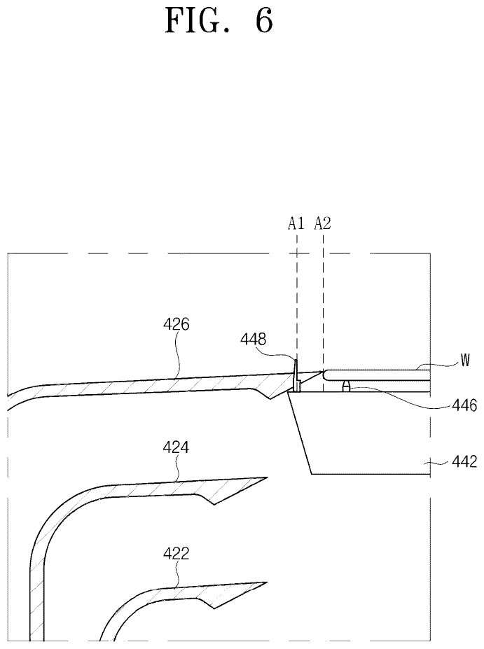

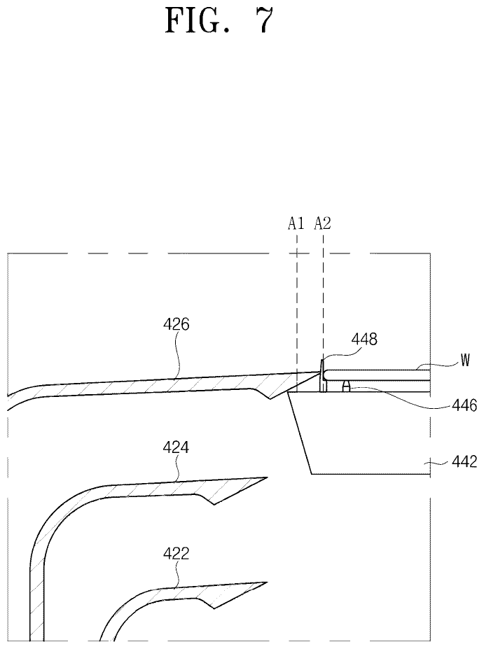

The substrate loading operation S10 is an operation of loading the substrate W onto the support unit 340. In the following, the process of loading the substrate onto the support unit will be described sequentially with reference to FIGS. 5 to 7. Referring to FIG. 5, the chuck pin 448 is positioned in the standby position A1. The processing container 420 descends. As the processing container 420 descends, the chuck pin 448 is inserted into the groove 426e formed in the upper wall 426b of the first cup 426. Thus, even though the upper wall 426b extends until the upper wall 42b interferes with the chuck pin 448, the substrate W may be loaded onto the support pin 446 without interference. Referring to FIG. 6, the transfer robot 320 delivers the substrate W onto the support pin 446. The transfer robot 320 is then moved back, and the substrate W is supported by the support pins 446. Referring to FIG. 7, the chuck pin 448 moves in a straight line from the standby position A1 to the support position A2. Accordingly, the chuck pin 448 supports the substrate W from the side. In one example, the chuck pin 448 may move in a straight line from the standby position A1 to the support position A2 in the space formed by the groove 426e. In one example, when the chuck pin 448 is positioned in the support position A2, the outer end 448a of the chuck pin 448 may have a greater distance to the center axis of the support plate 342 than the inner end 426d of the upper wall 426b. The inner end 426d of the upper wall 426b may extend to a position where it does not interfere with the substrate during lowering of the processing container 420. Thereafter, the processing container 420 rises and the substrate processing operation S20 is performed.

The substrate processing operation S20 adjusts the relative height of the first cup 426 and the second cup 324 depending on the type of treatment solution. In one example, the relative height of the first cup 426 and the second cup 324 may be adjusted such that when the substrate is processed with a first treatment solution, the first treatment solution is collected to the first inlet 331, and when the substrate is processed with a second treatment solution, the second treatment solution is collected to the second inlet 332.

The substrate unloading operation S30 is an operation of unloading the substrate W by lowering the processing container 420. First, the processing container 420 is lowered. As the processing container 420 is lowered, the chuck pin 448 is inserted back into the groove 426e. The chuck pin 448 then moves from the support position A2 to the standby position A1. Thereby, the substrate W is delivered from the chuck pin 448 to the support pin 446. The substrate W is again supported by the support pin 446. The transfer robot 320 then takes over the substrate W from the support pin 446 and transfers the substrate W to the transfer chamber 240.

Hereinafter, a method of cleaning a processing container by using the above-described substrate processing apparatus will be described.

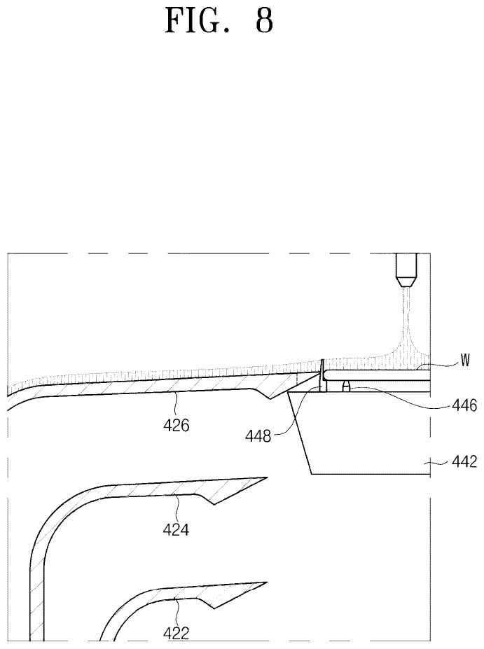

FIG. 8 is a diagram illustrating the operation of cleaning a substrate by using the substrate processing apparatus according to an exemplary embodiment of the present invention. Referring to FIG. 8, an exterior side of the first cup 426 is cleaned during the processing container cleaning operation S40. In the first cleaning operation S40, the substrate W is loaded. The substrate W is loaded onto the support plate 442 in the same way as in the substrate loading operation S10. In this case, the top end of the inner end 426d of the first cup 426 is positioned at a lower position than the substrate W. The cleaning solution nozzle 409 dispenses a cleaning solution onto the substrate W. The cleaning solution flows from the substrate W to the exterior side of the first cup 426. Contaminants adhering to the exterior side of the first cup 426 are cleaned by the cleaning solution.

Generally, the opening of the first cup 426 needs to be located such that the inner end 426d of the first cup 426 is further from the center axis of the support plate 342 than the outer end 448a of the chuck pin 448 in order to avoid interference between the first cup 426 and the chuck pin 448 during loading and unloading of the substrate. Accordingly, the opening of the processing container is wide, so that the treatment solution is easily scattered to the outside of the processing container 420. There is a problem in that the chemical solution scattered to the outside of the processing container 420 generates fume or the like and contaminates the substrate W when the substrate W is processed.

However, according to the exemplary embodiment of the present invention, by extending the upper wall of the first cup 426 to provide the narrow opening of the first cup 426, it is possible to inhibit the chemical solution from being scattered to the outside of the processing container 420 during rotation. Furthermore, by forming the groove 426e at the position corresponding to the chuck pin 448 in the inner end 426d of the first cup 426, the processing container 420 and the chuck pin 448 may be prevented from interfering (colliding) when the processing container 420 is lowered to transfer the substrate to the support unit by the transfer robot. Accordingly, the substrate W may be supported without interference with the chuck pin 448, and the exterior side of the first cup 426 may be cleaned. Accordingly, contamination of the substrate may be minimized during substrate processing.

In the example described above, the present invention has been described based on the case where the upper wall 426b of the first cup 426 is the integral type as an example. However, the present invention is not limited thereto, and as viewed above, the upper wall of the first cup is formed of a body part 427 in which the inner end 426d of the upper wall 426b of the first cup 426 coincides with inner ends 424d and 424c of the upper walls 424c and 422c of the other cups to provide openings of the same width, and a protrusion 428 detachably provided on an inner end 427a of the body part 427, and a groove 428b may be formed in the inner end 428a of the protrusion 428.

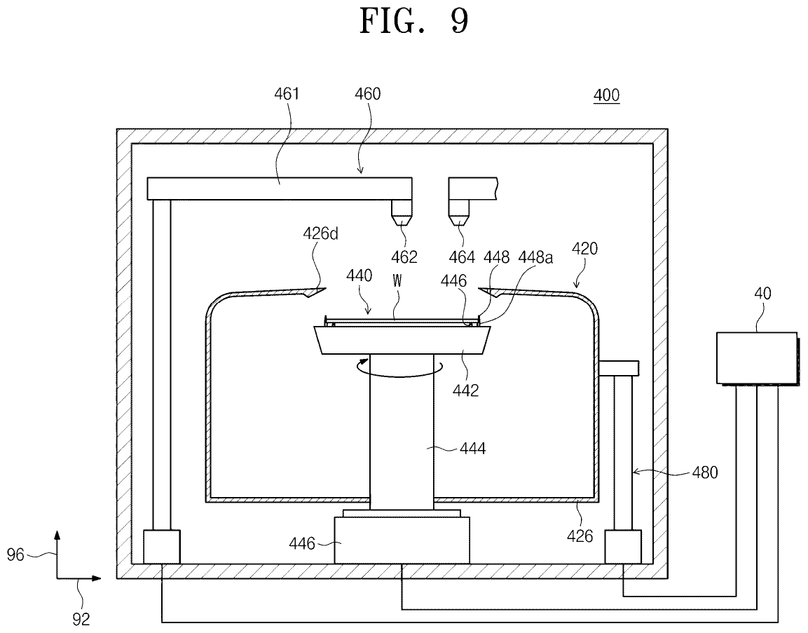

Further, in the example described above, the present invention has been described based on the case where the processing container 420 includes the plurality of cups 422, 424, and 426 in which the openings through which the treatment solution is introduced are stacked in an up and down direction as an example. However, the present invention is not limited thereto, and the processing container 420 may be provided only to the first cup 426, as illustrated in FIG. 9.

Further, the above example, the present invention has been described based on the process of providing the cleaning solution as the treatment solution and cleaning the substrate by using the cleaning solution as an example. However, the present exemplary embodiment is not limited to a cleaning process, but may be applied to various substrate processing processes using a liquid, such as an etching process, an ashing process, and a development process.

In addition, in the above example, the above example, the present invention has been described based on the case where the cups 422, 424, and 426 are integrally formed and moved up and down together by the lifting unit 420. However, the present invention is not limited thereto, and the first cup 426, the second cup 424, and the third cup 422 may each be independently driven.

The foregoing detailed description illustrates the present invention. Further, the above content illustrates and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. A substrate processing apparatus comprising:
a processing container having a processing space therein;
a support unit for supporting and rotating a substrate within the processing space; and
a nozzle unit for supplying a treatment solution to the substrate,
wherein the processing container includes a plurality of cups that encloses the processing space and is provided so that openings through which the treatment solution is introduced are stacked in an up and down direction,
each of the plurality of cups includes:
a sidewall; and
an upper wall extending from the sidewall toward the processing space, and
an inner end of an upper wall of a first cup, of which the upper wall is located at the uppermost side among the plurality of cups, protrudes further toward the processing space than an inner end of an upper wall of another cup.

2. The substrate processing apparatus of claim 1, wherein a groove is formed in the inner end of the upper wall of the first cup.

3. The substrate processing apparatus of claim 2, wherein the support unit includes:
a support plate on which the substrate is placed; and
a plurality of chuck pins provided to protrude upwardly from a top surface of the support plate, and supporting a lateral portion of the substrate when the substrate is processed.

4. The substrate processing apparatus of claim 3, wherein the chuck pin is inserted into the groove when a top end of the chuck pin is moved to a position higher than the inner end of the upper wall of the first cup.

5. The substrate processing apparatus of claim 3, wherein the inner end of the upper wall of the first cup has a shorter distance to a center axis of the support plate than an outer end of the chuck pin when viewed from above.

6. The substrate processing apparatus of claim 5, wherein the chuck pin is provided to be movable between a support position supporting the substrate and a standby position releasing the support of the substrate, and
a top end of the chuck pin passes through the groove when moved to a position higher than the inner end of the upper wall of the first cup while the chuck pin is in the standby position.

7. The substrate processing apparatus of claim 6, wherein the inner end of the upper wall of the first cup is provided to be sloped upwardly toward a center axis of the first cup.

8. The substrate processing apparatus of claim 7, wherein the upper wall of the first cup includes a body part and a protrusion,
when the body part is viewed from above, an inner end of the body part coincides with the inner end of the upper wall of the another cup,
the protrusion is detachably provided to the inner end of the body part, and
the groove is formed in an inner end of the protrusion.

9. A substrate processing apparatus comprising:
a processing container having a shape of a barrel with an open top and providing a processing space;
a support unit for supporting and rotating a substrate within the processing space; and
a liquid supply unit for supplying a treatment solution to the substrate supported on the support unit,
wherein the processing container includes:
a sidewall provided in a ring shape and surrounding the support unit; and
an upper wall extending from a top end of the sidewall towards a central axis of the support unit, and
a groove is formed at an inner end of the upper wall.

10. The substrate processing apparatus of claim 9, wherein the support unit includes:
a support plate on which the substrate is placed; and
a plurality of chuck pins provided to protrude upwardly from a top surface of the support plate, and supporting a lateral portion of the substrate when the substrate is processed.

11. The substrate processing apparatus of claim 10, wherein the chuck pin is provided to be movable between a support position supporting the substrate and a standby position releasing the support of the substrate, and
a top end of the chuck pin passes through the groove when moved to a position higher than the upper wall while the chuck pin is in the standby position.

12. The substrate processing apparatus of claim 11, wherein the inner end of the upper wall is provided to be closer to a center axis of the support plate than an outer end of the chuck pin in the standby position when viewed from above.

13. The substrate processing apparatus of claim 12, wherein the groove is formed at a position corresponding to the standby position.

14. The substrate processing apparatus of claim 12, wherein the groove is provided for insertion of the chuck pin when the top end of the chuck pin is moved to a position higher than the upper wall.

15. The substrate processing apparatus of claim 14, wherein the chuck pin is provided such that, when viewed from above, the outer end of the chuck pin at the support position is closer to the center axis of the support plate than the inner end of the upper wall.

16. The substrate processing apparatus of claim 15, wherein the upper wall is provided to be sloped upwardly toward the center axis of the support plate.

17. The substrate processing apparatus of claim 16, wherein a portion extending from the upper wall is a protrusion, and
the upper wall and the protrusion are separable.

18. A substrate processing apparatus comprising:
a processing container having a processing space therein;
a support unit for supporting and rotating a substrate within the processing space; and
a nozzle unit for supplying a treatment solution to the substrate,
wherein the processing container includes a plurality of cups that encloses the processing space and is provided so that openings through which the treatment solution is introduced are stacked in an up and down direction,
each of the plurality of cups includes:
a sidewall; and
an upper wall extending from the sidewall toward the processing space, and
an inner end of an upper wall of a first cup, of which the upper wall is located at the uppermost side among the plurality of cups, protrudes further toward the processing space than an inner end of an upper wall of another cup,
a groove is formed in the inner end of the upper wall of the first cup,
the chuck pin is provided to be movable between a support position supporting the substrate and a standby position releasing the support of the substrate, and
the groove is provided for insertion of the chuck pin when the top end of the chuck pin is moved to a position higher than the inner end of the upper wall of the first cup while the chuck pin is in the standby position.

19. The substrate processing apparatus of claim 18, wherein the plurality of cups further includes a second cup,
the second cup is located inside the first cup,
an upper wall of the second cup is provided parallel to the upper wall of the first cup, but is located lower than the upper wall of the first cup, and
the substrate processing apparatus further includes a lifting member for adjusting a relative height of the first cup and the second cup.

20. The substrate processing apparatus of claim 19, wherein the upper walls are provided to be sloped upwardly toward a center axis of the support unit.
